(19) United States
(12) Patent Application Publication
(10) Pub. No.: US 2025/0379118 A1
(43) Pub. Date: Dec. 11, 2025

(54) SYSTEMS AND METHODS FOR COOLING ELECTRONIC ASSEMBLIES

(71) Applicant: Toyota Motor Engineering & Manufacturing North America, Inc., Plano, TX (US)

(72) Inventors: Danny J. LOHAN, Bloomfield, MI (US); Feng ZHOU, Ann Arbor, MI (US); Shailesh N. JOSHI, Ann Arbor, MI (US)

(73) Assignee: Toyota Motor Engineering & Manufacturing North America, Inc., Plano, TX (US)

(21) Appl. No.: 18/738,708

(22) Filed: Jun. 10, 2024

(51) Int. Cl. H01L 23/427; H05K 1/02; H05K 1/18

(52) U.S. Cl. CPC H01L 23/427; H05K 1/0203; H05K 1/185

(57) ABSTRACT

An electronic assembly may include a power device assembly including a power device having a top face and a bottom face, a structured wick having an upper face and a lower face, the upper face of the structured wick coupled to the bottom face of the power device, a cap having a top face and a bottom face, the top face of the cap coupled to the bottom face of the structured wick, and a base substrate having an upper face, a lower face, a fluid inlet, a fluid outlet, and a groove. The bottom face of the cap is coupled to the groove of the base substrate. The power device assembly is embedded within a printed circuit board. The fluid inlet and fluid outlet of the base substrate are arranged in the lower face of the base substrate and are in fluid communication with a first fluid reservoir.

### FIELD

The present disclosure relates to systems for cooling electronic assemblies.

### TECHNICAL BACKGROUND

Electronic assemblies, such as those used for electric vehicles, may generate significant heat during operation which requires cooling in order to keep the electronic assemblies within their optimal operating temperature range. Conventional cooling systems can involve passing a cooling fluid across electronic assembles to cool the electronic assembly and maintain the electronic assembly within its optimal operating temperature range.

### SUMMARY

Electronic assemblies, such as those used on electric vehicles, generate heat during operation. In order to operate effectively, electronic assemblies should be maintained within an ideal operating temperature range. Thus, electronic assemblies should be cooled.

Oftentimes cooling fluid may be pumped across electronic assemblies to cool the electronic assemblies. It may be challenging to create an adequate flow of cooling fluid across the heat generating devices of the electronic assemblies particularly when the heat generating devices are embedded within a printed circuit board. Therefore, there exists a need for an electronic assemblies cooling system which can supply an adequate flow of cooling fluid to the heat generating devices even when the heat generating devices are embedded within a printed circuit board.

The present embodiments can provide a more efficient electronic assembly cooling system than conventional electronic assembly cooling systems by utilizing a grooved base substrate and structured wick to house a power device assembly and draw cooling fluid to cool the electronic assembly.

Embodiments generally include a power device assembly including a power device, a structured wick, and a cap embedded within a groove of a base substrate. The base substrate and power device assembly may be embedded within a printed circuit board. Cooling fluid may be flowed from a fluid reservoir through passages in the base substrate to be drawn across the structured wick and remove heat from the power device. Heated cooling fluid and vaporized cooling fluid may be vented out of the base substrate back into the fluid reservoir. The cooling fluid may then be cooled and/or replaced with fresh cooling fluid to continue to cool the power device assembly. This can provide the advantage of adequate cooling fluid flow across a power electronic assembly embedded within a printed circuit board.

According to one embodiment, an electronic assembly may include a power device assembly including a power device having a top face and a bottom face, a structured wick having an upper face and a lower face, the upper face of the structured wick coupled to the bottom face of the power device, a cap having a top face and a bottom face, the top face of the cap coupled to the bottom face of the structured wick, and a base substrate having an upper face, a lower face, a fluid inlet, a fluid outlet, and a groove, wherein the bottom face of the cap is coupled to the groove of the base substrate, wherein the power device assembly is embedded within a printed circuit board, and the fluid inlet and fluid outlet of the base substrate are arranged in the lower face of the base substrate and are in fluid communication with a first fluid reservoir.

According to another embodiment, an electronic assembly may include a power device assembly including a power device having a top face and a bottom face, a structured wick having an upper face and a lower face, the upper face of the structured wick coupled to the bottom face of the power device, a cap having a top face and a bottom face, the top face of the cap coupled to the bottom face of the structured wick, and a base substrate having an upper face, a lower face, a fluid inlet, a fluid outlet, and a groove, wherein the bottom face of the cap is coupled to the groove of the base substrate, wherein the power device assembly is embedded within a printed circuit board, and the fluid inlet and fluid outlet of the base substrate are arranged in the upper face of the base substrate and are in fluid communication with a first fluid reservoir.

According to a further embodiment, an electronic assembly may include a power device assembly including a power device having a top face and a bottom face, a structured wick having an upper face and a lower face, the upper face of the structured wick coupled to the bottom face of the power device, a cap having a top face and a bottom face, the top face of the cap coupled to the bottom face of the structured wick, and a base substrate having an upper face, a lower face, a fluid inlet, a fluid outlet, and a groove, wherein the bottom face of the cap is coupled to the groove of the base substrate, wherein the power device assembly is embedded within a printed circuit board, the fluid inlet and fluid outlet of the base substrate are arranged in the upper face of the base substrate and are in fluid communication with a first fluid reservoir, and the lower face of the base substrate is in fluid communication with a second fluid reservoir.

Additional features and advantages of the technology described in this disclosure will be set forth in the detailed description which follows, and in part will be readily apparent to those skilled in the art from the description or recognized by practicing the technology as described in this disclosure, including the detailed description which follows, the claims, as well as the appended drawings.

### BRIEF DESCRIPTION OF THE DRAWINGS

The following detailed description of the present disclosure may be better understood when read in conjunction with the following drawings in which:

FIG. 1 schematically depicts a front view of a power device assembly according to one or more embodiments shown and described herein;

FIG. 2 schematically depicts a front view of an electronic assembly according to one or more embodiments shown and described herein;

FIG. 3 schematically depicts a section view of an electronic assembly according to one or more embodiments shown and described herein;

FIG. 4 schematically depicts a front view of an electronic assembly according to one or more embodiments shown and described herein;

FIG. 5 schematically depicts a front view of an electronic assembly according to one or more embodiments shown and described herein; and

FIG. 6 schematically depicts a section view of an electronic assembly according to one or more embodiments shown and described herein.

Reference will now be made in greater detail to various embodiments of the present disclosure, some embodiments of which are illustrated in the accompanying drawings. Whenever possible, the same reference numerals will be used throughout the drawings to refer to the same or similar parts.

### DETAILED DESCRIPTION

Embodiments of the present disclosure are directed to electronics assembly cooling systems which provide for structures to pass a cooling fluid to remove heat from a power device assembly. The electronics assembly cooling systems described herein may include a power device assembly placed within a groove of a base substrate which is embedded within a printed circuit board. Cooling fluid may be flowed to the power device assembly through a fluid inlet formed in the base substrate. The cooling fluid may be drawn across the power device through a structured wick. Cooling fluid may be flowed out of the power device assembly through vapor outlets and fluid outlets. The cooling fluid may then be cooled or replaced so that a new portion of cooling fluid may be used to cool the electronics assembly.

Conventional electronic assembly cooling systems may not flow a sufficient amount of cooling fluid to the heat generating devices, particularly when the heat generating devices are embedded within a printed circuit board. Embodiments can more effectively flow cooling fluid to heat generating devices compared to conventional cooling systems.

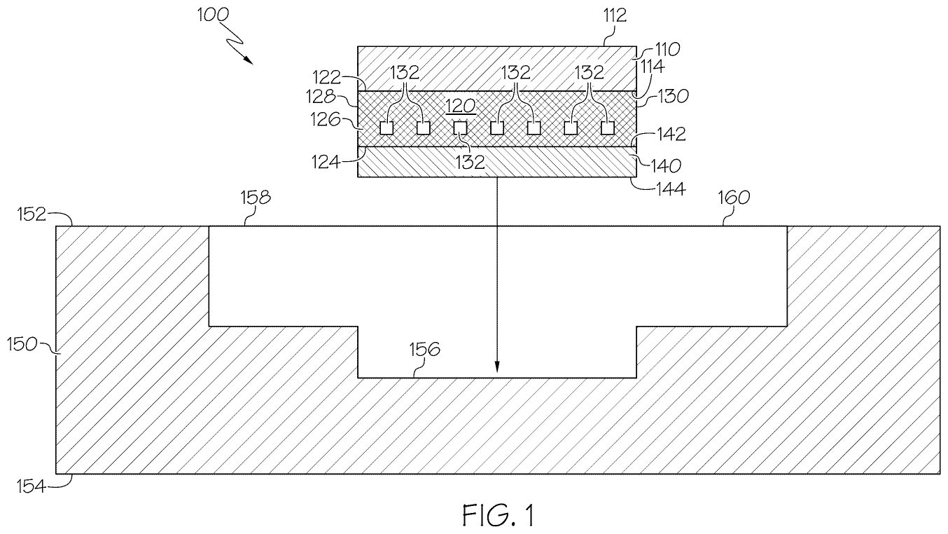

Referring now to FIG. 1, a front view of a power device assembly 100 and a base substrate 150 is shown. The power device assembly 100 includes a power device 110. The power device 110 may be a MOSFET, an IGBT, or any other suitable power device 110. The power device 110 includes a top face 112 and a bottom face 114.

The power device assembly 100 includes a structured wick 120. The structured wick 120 includes an upper face 122 and a lower face 124. As illustrated, the upper face 122 of the structured wick 120 is coupled to the bottom face 114 of the power device 110, but it should be understood that, in embodiments, the structured wick 120 and power device 110 may be arranged in any other suitable arrangement, such as the lower face 124 of the structured wick 120 being coupled to the top face 112 of the power device 110.

The structured wick 120 provides capillaries to wick cooling fluid towards the power device 110. The structured wick 120 may be made of any suitable material, including but not limited to copper, aluminum, stainless steel, or any other suitable material. The structured wick 120 may include a manifold 126. The manifold 126 may include a fluid inlet 128, a fluid outlet 130, and a vapor outlet 132.

The power device assembly 100 further includes a cap 140 that has a top face 142 and a bottom face 144. As illustrated, the top face 142 of the cap 140 is coupled to the lower face 124 of the structured wick 120, but it should be understood that, in embodiments, the cap 140 and the structured wick 120 may be arranged in any other suitable arrangement, such as the bottom face 144 of the cap 140 being coupled to the upper face 122 of the structured wick 120.

The cap 140 may be made of any suitable thermally conductive material, including but not limited to copper, aluminum, stainless steel, or any other suitable material.

The power device assembly 100 is coupled to a base substrate 150. The base substrate 150 may be a block or substrate which is configured to securedly hold the power device assembly 100. The base substrate 150 may be constructed of any suitable material, including but not limited to copper, a copper substrate, or any other suitable material. In embodiments, the base substrate 150 is made of an electrically conductive material.

The base substrate 150 includes a upper face 152, a lower face 154, and a groove 156. As illustrated, the groove 156 may be formed in the upper face 152. However it should be understood that, in embodiments, the groove 156 may be formed in other portions of the base substrate 150, including but not limited to in the lower face 154. The groove 156 may be shaped and sized so as to allow the power device assembly 100 to be disposed therein.

The base substrate 150 includes a fluid inlet 158 and a fluid outlet 160. The fluid inlet 158 is fluidly coupled to the fluid inlet 128 of the structured wick 120. The fluid outlet 160 is fluidly coupled to the fluid outlet 130 and vapor outlet 132 of the structured wick 120. The fluid inlet 158 and fluid outlet 160 may allow for the passage of cooling fluid through the structured wick 120, as will be described in more detail herein.

The power device assembly 100 may be coupled to the base substrate 150 through any suitable coupling mechanism, including but not limited to silver sintering, soldering, or any other suitable coupling mechanism.

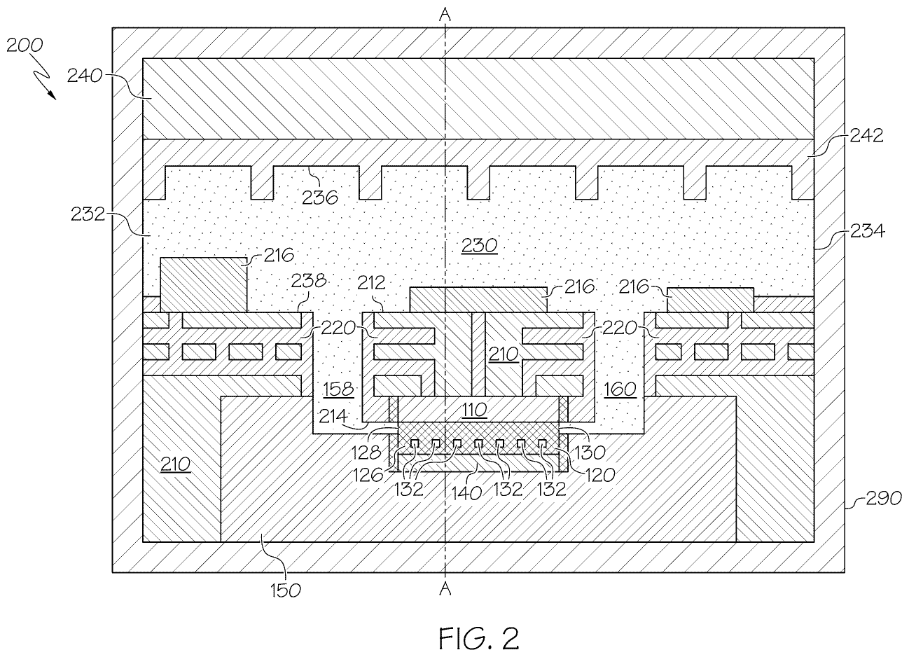

Referring now to FIG. 2, a view of an electronic assembly 200 is shown. The electronic assembly 200 includes the power device assembly 100 and base substrate 150 similar to the embodiment shown and described above in FIG. 1.

The electronic assembly 200 further includes a printed circuit board (PCB) 210. The PCB 210 may have an upper face 212 and a bottom face 214. One or more electronic components 216 may be electronically coupled to the upper face 212 of the PCB 210. The one or more electronic components 216 may be various types of electronic components, including but not limited to logic devices, CPUs, or any other suitable type of electronic components.

The one or more electronic components 216 may be electrically coupled to the base substrate 150 through one or more coupling paths 220. The one or more coupling paths 220 may be made of any suitable electrically conductive material, including but not limited to copper or aluminum.

The electronic assembly 200 includes a first fluid reservoir 230. The first fluid reservoir 230 may be configured to allow a cooling fluid to be passed therethrough. The cooling fluid may be any suitable cooling fluid, including but not limited to water, glycol, water-glycol solutions, or any other suitable cooling fluid. In some embodiments, the cooling fluid may be a dielectric cooling fluid.

The first fluid reservoir 230 may include a fluid inlet 232 and a fluid outlet 234. The fluid inlet 232 and the fluid outlet 234 may be fluidly coupled to various other components not shown, such as fluid pipes, pumps, and heat exchangers which may circulate and cool the cooling fluid. The first fluid reservoir 230 may include a top surface 236 and a bottom surface 238 opposite the top surface 236. A boundary layer 242 may be placed above the top surface 236 of the first fluid reservoir 230.

The one or more electronic components 216 may be immersed in the cooling fluid in the first fluid reservoir 230, such that the cooling fluid may cool the one or more electronic components 216.

The first fluid reservoir 230 is fluidly coupled to the fluid inlet 158 and fluid outlet 160 of the base substrate 150. Fluid may be drawn from the fluid reservoir into the fluid inlet 158 and then into the fluid inlet 128 of the manifold 126 of the structured wick 120. The structured wick 120 may draw the cooling fluid through the manifold 126. Heat from the power device assembly 100 may be transferred to the cooling fluid, such that some or all of the cooling fluid may be vaporized. Vaporized cooling fluid may be vented from the manifold 126 out the vapor outlet 132. Non-vaporized cooling fluid may be vented from the manifold 126 out of the fluid outlet 130. The fluid outlet 130 may be fluidly coupled to the fluid outlet 160 of the base substrate 150.

The electronic assembly 200 may include a secondary heat generating device 240. The secondary heat generating device 240 may be, as a non-limiting example, a capacitor. In some embodiments, the secondary heat generating device 240 may be coupled to the top surface 236 of the first fluid reservoir 230, such that heat from the secondary heat generating device 240 may be transferred to the cooling fluid held within the first fluid reservoir 230.

In some embodiments, the boundary layer 242 may be placed between the secondary heat generating device 240 and the top surface 236 of the first fluid reservoir. The boundary layer 242 may have various features such as fins or heat sinks which may project into the first fluid reservoir 230. The fins or heat sinks may increase the surface area of the boundary layer 242 which may enhance heat transfer. In other embodiments, the secondary heat generating device 240 may be in direct contact with the cooling fluid held within the first fluid reservoir 230.

The electronic assembly 200 may include a casing 290. The casing 290 may surround the outer edges of the secondary heat generating device 240, the PCB 210, the base substrate 150, and the first fluid reservoir 230. The casing 290 may be made of any suitable material, including plastic or metal.

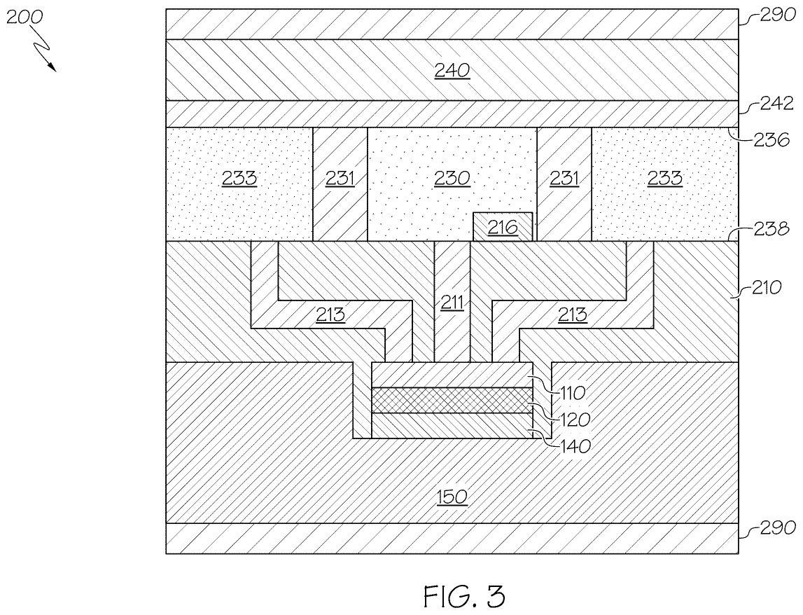

Referring now to FIG. 3, a section view of the electronic assembly 200 along cutting line A-A of FIG. 2 is shown. The electronic assembly 200 may include one or more vapor channels 233. Each of the one or more vapor channels 233 may be fluidly coupled to the power device assembly 100 through one or more vapor ducts 213. The one or more vapor ducts 213 may be configured through the PCB 210. The one or more vapor channels 233 may be configured to allow for vaporized cooling fluid to be vented through the one or more vapor channels 233.

The first fluid reservoir 230 may be fluidly coupled to the power device assembly 100 through one or more fluid channels 211. The one or more fluid channels 211 may be configured through the PCB 210. The one or more fluid channels 211 may be configured to allow for cooling fluid which has been heated but not vaporized to be vented through the first fluid reservoir 230.

The first fluid reservoir 230 and the one or more vapor channels 233 may be separated by one or more dividers 231. The one or more dividers 231 may keep the flow of liquid cooling fluid and vaporized cooling fluid separate from one another. This may reduce pressure drop and turbulence within the electronic assembly 200.

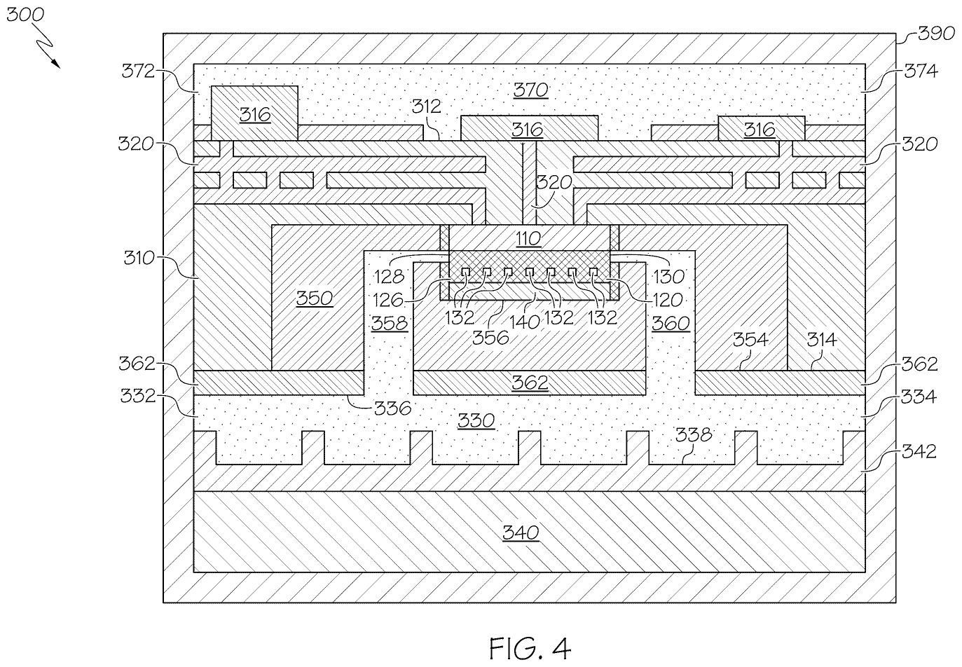

Referring now to FIG. 4, a view of another example electronic assembly 300 is shown. The electronic assembly 300 includes the power device assembly 100 similar to the embodiment shown and described above in FIG. 1, embedded within a different structure.

The power device assembly 100 is coupled to a base substrate 350. The base substrate 350 includes an upper face 352 and a lower face 354. The base substrate 350 includes a groove 356. The groove 356 is formed in the lower face 354. The groove 356 may be shaped and sized so as to allow the power device assembly 100 to be disposed therein.

The base substrate 350 includes a fluid inlet 358 and a fluid outlet 360. The fluid inlet 358 and the fluid outlet 360 are each formed in the lower face 354 of the base substrate 350. The fluid inlet 358 and fluid outlet 360 may allow for the passage of cooling fluid through the structured wick 120.

The electronic assembly 300 further includes a printed circuit board (PCB) 310. The PCB 310 may have an upper face 312 and a bottom face 314. One or more electronic components 316 may be electronically coupled to the upper face 312 of the PCB 310. The one or more electronic components 316 may be various types of electronic components, including but not limited to logic devices, CPUs, or any other suitable type of electronic components.

The one or more electronic components 316 may be electrically coupled to the base substrate 350 through one or more coupling paths 320. The one or more coupling paths 320 may be made of any suitable electrically conductive material, including but not limited to copper or aluminum.

The electronic assembly 300 includes a first fluid reservoir 330. The first fluid reservoir 330 may be configured to allow a cooling fluid to be passed therethrough. The cooling fluid may be any suitable cooling fluid, including but not limited to water, glycol, water-glycol solutions, or any other suitable cooling fluid. In some embodiments, the cooling fluid may be a dielectric cooling fluid.

The first fluid reservoir 330 may include a fluid inlet 332 and a fluid outlet 334. The fluid inlet 332 and the fluid outlet 334 may be fluidly coupled to various other components not show, such as fluid pipes, pumps, and heat exchangers which may circulate and cool the cooling fluid. The first fluid reservoir 330 may include a top surface 336 and a bottom surface 338 opposite the top surface 336.

The first fluid reservoir 330 is fluidly coupled to the fluid inlet 358 and fluid outlet 360 of the base substrate 350. Fluid may be drawn from the first fluid reservoir 330 into the fluid inlet 358 and then into the fluid inlet 128 of the manifold 126 of the structured wick 120. The structured wick 120 may draw the cooling fluid through the manifold 126. Heat from the power device assembly 100 may be transferred to the cooling fluid, such that some or all of the cooling fluid may be vaporized. Vaporized cooling fluid may be vented from the manifold 126 out the vapor outlet 132. Non-vaporized cooling fluid may be vented from the manifold 126 out of the fluid outlet 130. The fluid outlet 130 may be fluidly coupled to the fluid outlet 360 of the base substrate 350.

The electronic assembly 300 includes a second fluid reservoir 370. The second fluid reservoir 370 may include a fluid inlet 372 and a fluid outlet 374. The fluid inlet 372 and the fluid outlet 374 may be fluidly coupled to various other components not show, such as fluid pipes, pumps, and heat exchangers which may circulate and cool the cooling fluid. The second fluid reservoir 370 may include a top surface 376 and a bottom surface 378 opposite the top surface 376. The electronic assembly 300 may include a casing 390. The casing 390 may surround the outer edges of the secondary heat generating device 340, the PCB 310, the base substrate 350, the first fluid reservoir 330, and the second fluid reservoir 370. The casing 390 may be made of any suitable material, including plastic or metal.

In some embodiments, the cooling fluid circulated in the second fluid reservoir 370 may be from the same cooling loop as the cooling fluid circulated in the first fluid reservoir 330. In other embodiments, the cooling fluid circulated in the second fluid reservoir 370 may be separate from the cooling fluid circulated in the first fluid reservoir 330.

The one or more electronic components 316 may be immersed in the cooling fluid in the second fluid reservoir 370, such that the cooling fluid may cool the one or more electronic components 316.

The electronic assembly 300 may include a secondary heat generating device 340. The secondary heat generating device 340 may be, as a non-limiting example, a capacitor. The secondary heat generating device 340 may be coupled to the bottom surface 338 of the first fluid reservoir 330, such that heat from the secondary heat generating device 340 may be transferred to the cooling fluid held within the first fluid reservoir 330.

In some embodiments, a boundary layer 342 may be placed between the secondary heat generating device 340 and the bottom surface 338 of the first fluid reservoir 330. The boundary layer 342 may have various features such as fins or heat sinks which may project into the first fluid reservoir 330. The fins or heat sinks may increase the surface area of the boundary layer 342 which may enhance heat transfer. In other embodiments, the secondary heat generating device 340 may be in direct contact with the cooling fluid held within the first fluid reservoir 330.

The electronic assembly 300 may include an isolation layer 362. The isolation layer 362 may be coupled to the lower face 354 of the base substrate 350 and the bottom face 314 of the PCB 310.

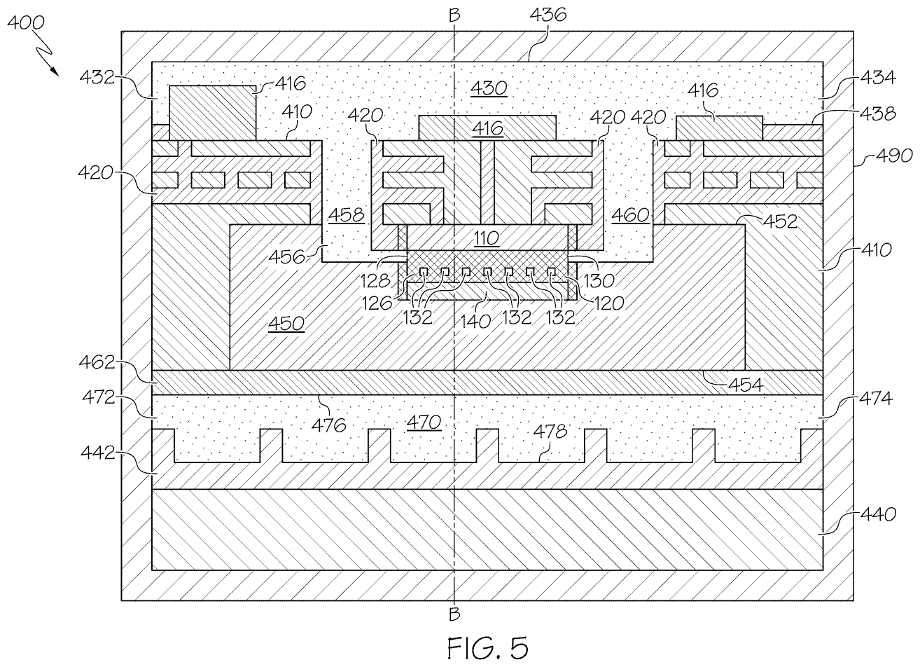

Referring now to FIG. 5, a view of another example electronic assembly 400 is shown. The electronic assembly 400 includes the power device assembly 100 similar to the embodiment shown and described above in FIG. 1, embedded within a different structure.

The power device assembly 100 is coupled to a base substrate 450. The base substrate 450 includes an upper face 452 and a lower face 454. The base substrate 450 includes a groove 456. The groove 456 is formed in the upper face 452. The groove 456 may be shaped and sized so as to allow the power device assembly 100 to be disposed therein.

The base substrate 450 includes a fluid inlet 458 and a fluid outlet 460. The fluid inlet 458 and the fluid outlet 460 are each formed in the upper face 452 of the base substrate 450. The fluid inlet 458 and fluid outlet 460 may allow for the passage of cooling fluid through the structured wick 120.

The electronic assembly 400 further includes a printed circuit board (PCB) 410. The PCB 410 may have an upper face 412 and a bottom face 414. One or more electronic components 416 may be electronically coupled to the upper face 412 of the PCB 410. The one or more electronic components 416 may be various types of electronic components, including but not limited to logic devices, a CPU, or any other suitable electronic component.

The one or more electronic components 416 may be electronically coupled to the base substrate 450 through one or more coupling paths 420. The one or more coupling paths 420 may be made of any suitable electrically conductive material, including but not limited to copper or aluminum.

The electronic assembly 400 includes a first fluid reservoir 430. The first fluid reservoir 430 may be configured to allow a cooling fluid to be passed therethrough. The cooling fluid may be any suitable cooling fluid, including but not limited to water, glycol, water-glycol solutions, or any other suitable cooling fluid. In some embodiments, the cooling fluid may be a dielectric cooling fluid.

The first fluid reservoir 430 may include a fluid inlet 432 and a fluid outlet 434. The fluid inlet 432 and the fluid outlet 434 may be fluidly coupled to various other components not shown, such as fluid pipes, pumps, and heat exchangers which may circulate and cool the cooling fluid. The first fluid reservoir 430 may include a top surface 436 and a bottom surface 438 opposite the top surface 436.

The first fluid reservoir 430 is fluidly coupled to the fluid inlet 458 and fluid outlet 460 of the base substrate 450. Fluid may be drawn from the fluid reservoir into the fluid inlet 158 and then into the fluid inlet 128 of the manifold 126 of the structured wick 120. The structured wick 120 may draw the cooling fluid through the manifold 126. Heat from the power device assembly 100 may be transferred to the cooling fluid, such that some or all of the cooling fluid may be vaporized. Vaporized cooling fluid may be vented from the manifold 126 out the vapor outlet 132. Non-vaporized cooling fluid may be vented from the manifold 126 out of the fluid outlet 130. The fluid outlet 130 may be fluidly coupled to the fluid outlet 460 of the base substrate 450.

The electronic assembly 400 includes a second fluid reservoir 470. The second fluid reservoir 470 may include a fluid inlet 472 and a fluid outlet 474. The fluid inlet 472 and the fluid outlet 474 may be fluidly coupled to various other components not show, such as fluid pipes, pumps, and heat exchangers which may circulate and cool the cooling fluid. The second fluid reservoir 470 may include a top surface 476 and a bottom surface 478 opposite the top surface 476.

In some embodiments, the cooling fluid circulated in the second fluid reservoir 470 may be from the same cooling loop as the cooling fluid circulated in the first fluid reservoir 430. In other embodiments, the cooling fluid circulated in the second fluid reservoir 470 may be separate from the cooling fluid circulated in the first fluid reservoir 430.

The one or more electronic components 416 may be immersed in the cooling fluid in the second fluid reservoir 470, such that the cooling fluid may cool the one or more electronic components 416.

The electronic assembly 400 may include a secondary heat generating device 440. The secondary heat generating device 440 may be, as a non-limiting example, a capacitor. The secondary heat generating device 440 may be coupled to the bottom surface 438 of the first fluid reservoir 430, such that heat from the secondary heat generating device 440 may be transferred to the cooling fluid held within the first fluid reservoir 430.

In some embodiments, a boundary layer 442 may be placed between the secondary heat generating device 440 and the bottom surface 438 of the fluid reservoir. The boundary layer 442 may have various features such as fins or heat sinks which may project into the first fluid reservoir 430. The fins or heat sinks may increase the surface area of the boundary layer 442 which may enhance heat transfer. In other embodiments, the secondary heat generating device 440 may be in direct contact with the cooling fluid held within the first fluid reservoir 430.

The electronic assembly 400 may include a casing 490. The casing 490 may surround the outer edges of the secondary heat generating device 440, the PCB 410, the base substrate 450, the first fluid reservoir 430, and the second fluid reservoir 470. The casing 490 may be made of any suitable material, including plastic or metal.

The electronic assembly 400 may include an isolation layer 462. The isolation layer 462 may be coupled to the lower face 454 of the base substrate 450 and the bottom face 414 of the PCB 410.

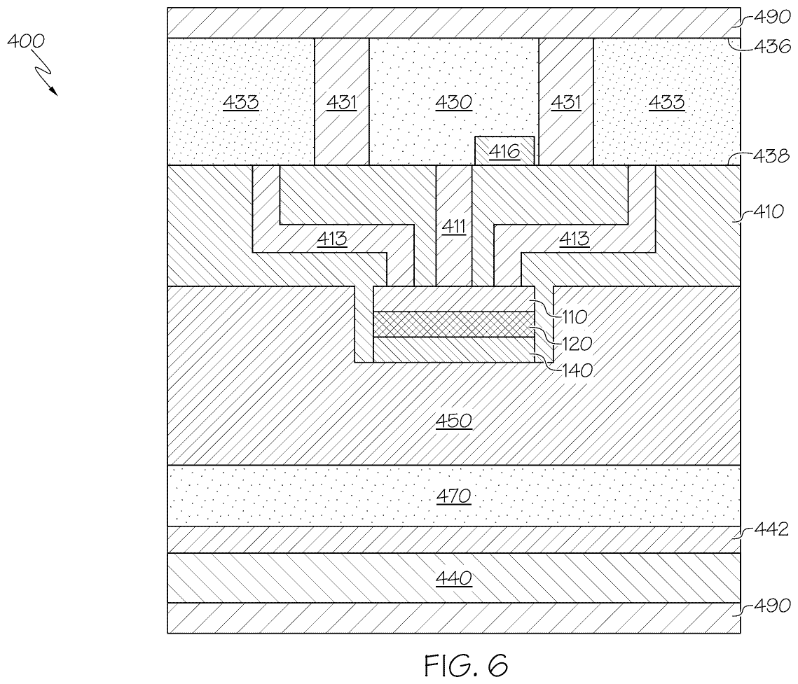

Referring now to FIG. 6, a section view of the electronic assembly 400 along cutting line B-B of FIG. 5 is shown. The electronic assembly 400 may include one or more vapor channels 433. Each of the one or more vapor channels 433 may be fluidly coupled to the power device assembly 100 through one or more vapor ducts 413. The one or more vapor ducts 413 may be configured through the PCB 410. The one or more vapor channels 433 may be configured to allow for vaporized cooling fluid to be vented through the one or more vapor channels 433.

The first fluid reservoir 430 may be fluidly coupled to the power device assembly 100 through one or more fluid channels 411. The one or more fluid channels 411 may be configured through the PCB 410. The one or more fluid channels 411 may be configured to allow for cooling fluid which has been heated but not vaporized to be vented through the first fluid reservoir 430.

The first fluid reservoir 430 and the one or more vapor channels 433 may be separated by one or more dividers 431. The one or more dividers 431 may keep the flow of liquid cooling fluid and vaporized cooling fluid separate from one another. This may reduce pressure drop and turbulence within the electronic assembly 400.

Accordingly embodiments of the present disclosure provide an electronic assembly cooling system which may more effectively supply cooling fluid to a power device assembly embedded within a printed circuit board. Particularly, the system may include a power device assembly including a power device, a structured wick, and a cap embedded within a groove of a base substrate. The base substrate and power device assembly may be embedded within a printed circuit board. Cooling fluid may be flowed from a fluid reservoir through passages in the base substrate to be drawn across the structured wick and remove heat from the power device. Heated cooling fluid and vaporized cooling fluid may be vented out of the base substrate back into the fluid reservoir.

It may be noted that one or more of the following claims utilize the terms “where,” “wherein,” or “in which” as transitional phrases. For the purposes of defining the present technology, it may be noted that these terms are introduced in the claims as an open-ended transitional phrase that are used to introduce a recitation of a series of characteristics of the structure and should be interpreted in like manner as the more commonly used open-ended preamble term “comprising.”

It should be understood that any two quantitative values assigned to a property may constitute a range of that property, and all combinations of ranges formed from all stated quantitative values of a given property are contemplated in this disclosure.

Having described the subject matter of the present disclosure in detail and by reference to specific embodiments, it may be noted that the various details described in this disclosure should not be taken to imply that these details relate to elements that are essential components of the various embodiments described in this disclosure, even in casings where a particular element may be illustrated in each of the drawings that accompany the present description. Rather, the claims appended hereto should be taken as the sole representation of the breadth of the present disclosure and the corresponding scope of the various embodiments described in this disclosure. Further, it will be apparent that modifications and variations are possible without departing from the scope of the appended claims.

What is claimed is:

1. An electronic assembly comprising:
a power device assembly comprising:
a power device having a top face and a bottom face;
a structured wick having an upper face and a lower face, the upper face of the structured wick coupled to the bottom face of the power device;
a cap having a top face and a bottom face, the top face of the cap coupled to the bottom face of the structured wick; and
a base substrate having an upper face, a lower face, a fluid inlet, a fluid outlet, and a groove, wherein the bottom face of the cap is coupled to the groove of the base substrate;
wherein the power device assembly is embedded within a printed circuit board, and the fluid inlet and fluid outlet of the base substrate are arranged in the lower face of the base substrate and are in fluid communication with a first fluid reservoir.

2. The electronic assembly of claim 1, wherein the first fluid reservoir further comprises a top surface and a bottom surface, and a secondary electronic component is coupled to the lower face of the first fluid reservoir.

3. The electronic assembly of claim 1, further comprising one or more electronic components arranged on an upper surface of the printed circuit board, wherein the one or more electronic components are electronically coupled to the base substrate.

4. The electronic assembly of claim 1, further comprising an isolation layer coupled to lower face of the base substrate.

5. The electronic assembly of claim 1, wherein the electronic assembly is disposed inside of a casing.

6. The electronic assembly of claim 1, wherein the structured wick further comprises a manifold, the manifold having a fluid inlet, a fluid outlet, and a vapor outlet.

7. An electronic assembly comprising:
a power device assembly comprising:
a power device having a top face and a bottom face;
a structured wick having an upper face and a lower face, the upper face of the structured wick coupled to the bottom face of the power device;
a cap having a top face and a bottom face, the top face of the cap coupled to the bottom face of the structured wick; and
a base substrate having an upper face, a lower face, a fluid inlet, a fluid outlet, and a groove, wherein the bottom face of the cap is coupled to the groove of the base substrate;
wherein the power device assembly is embedded within a printed circuit board, and the fluid inlet and fluid outlet of the base substrate are arranged in the upper face of the base substrate and are in fluid communication with a first fluid reservoir.

8. The electronic assembly of claim 7, wherein a cooling fluid is circulated within the electronic assembly, the cooling fluid comprising a dielectric cooling fluid.

9. The electronic assembly of claim 7, wherein the electronic assembly includes one or more vapor channels fluidly coupled to the power device assembly, the one or more vapor channels separated from the first fluid reservoir by one or more dividers between the first fluid reservoir and the one or more vapor channels.

10. The electronic assembly of claim 7, wherein the first fluid reservoir further comprises a top surface and a bottom surface, and a secondary electronic component is coupled to the upper face of the first fluid reservoir.

11. The electronic assembly of claim 7, further comprising one or more electronic components arranged on an upper surface of the printed circuit board, wherein the one or more electronic components are electronically coupled to the base substrate.

12. The electronic assembly of claim 7, wherein the electronic assembly is disposed inside of a casing.

13. The electronic assembly of claim 7, wherein the structured wick further comprises a manifold, the manifold having a fluid inlet, a fluid outlet, and a vapor outlet.

14. An electronic assembly comprising:
a power device assembly comprising:
a power device having a top face and a bottom face;
a structured wick having an upper face and a lower face, the upper face of the structured wick coupled to the bottom face of the power device;
a cap having a top face and a bottom face, the top face of the cap coupled to the bottom face of the structured wick; and
a base substrate having an upper face, a lower face, a fluid inlet, a fluid outlet, and a groove, wherein the bottom face of the cap is coupled to the groove of the base substrate;
wherein the power device assembly is embedded within a printed circuit board, the fluid inlet and fluid outlet of the base substrate are arranged in the upper face of the base substrate and are in fluid communication with a first fluid reservoir, and the lower face of the base substrate is in fluid communication with a second fluid reservoir.

15. The electronic assembly of claim 14, wherein a cooling fluid is circulated within the electronic assembly, the cooling fluid comprising a dielectric cooling fluid.

16. The electronic assembly of claim 14, wherein the electronic assembly includes one or more vapor channels fluidly coupled to the power device assembly, the one or more vapor channels separated from the first fluid reservoir by one or more dividers between the first fluid reservoir and the one or more vapor channels.

17. The electronic assembly of claim 14, wherein the second fluid reservoir further comprises a top surface and a bottom surface, and a secondary electronic component is coupled to the top surface of the second fluid reservoir.

18. The electronic assembly of claim 14, further comprising one or more electronic components arranged on an upper surface of the printed circuit board, wherein the one or more electronic components are electronically coupled to the base substrate.

19. The electronic assembly of claim 14, wherein the electronic assembly is disposed inside of a casing.

20. The electronic assembly of claim 14, wherein the structured wick further comprises a manifold, the manifold having a fluid inlet, a fluid outlet, and a vapor outlet.
